(19) United States
(12) Patent Application Publication
(10) Pub. No.: US 2012/0181533 A1
(43) Pub. Date: Jul. 19, 2012

(54) THIN FILM TRANSISTOR ARRAY PANEL

(75) Inventors: Hyeong Suk YOO, Yongin-si (KR); Joo-Han KIM, Yongin-si (KR); Je Hun LEE, Seoul (KR); Seong-Hun KIM, Seoul (KR); Jung Kyu LEE, Seoul (KR); Chang Oh JEONG, Suwon-si (KR)

(73) Assignee: SAMSUNG ELECTRONICS CO., LTD., Suwon-si (KR)

(21) Appl. No.: 13/243,649

(22) Filed: Sep. 23, 2011

(30) Foreign Application Priority Data
Jan. 19, 2011 (KR) 10-2011-0005482

(51) Int. Cl. H01L 29/786; H01L 29/24; H01L 29/04; H01L 29/22; H01L 21/44

(52) U.S. Cl. 257/43; 438/104; 257/57; 257/66; 257/E29.003; 257/E29.068; 257/E29.095; 257/E29.296; 257/E21.476

(57) ABSTRACT

A thin film transistor array panel includes: an substrate; a gate line positioned on the substrate; a data line intersecting the gate line; a thin film transistor connected to the gate line and the data line; a gate insulating layer between the gate electrode of the thin film transistor and the semiconductor of the thin film transistor; a pixel electrode connected to the thin film transistor; and a passivation layer positioned between the pixel electrode and the thin film transistor, wherein at least one of the gate insulating layer and the passivation layer includes a silicon nitride layer, and the silicon nitride layer includes hydrogen content at less than 2×10²² cm³ or 4 atomic %.

### CROSS-REFERENCE TO RELATED APPLICATION

This application claims priority to and the benefit of Korean Patent Application No. 10-2011-0005482 filed on Jan. 19, 2011, which is hereby incorporated by reference for all purposes as if fully set forth herein.

### BACKGROUND

1. Field

The present invention relates to a thin film transistor array panel and a manufacturing method thereof.

2. Discussion of the Background

A thin film transistor is used as a switching element to independently drive each pixel in a flat display device such as a liquid crystal display or an organic light emitting device. The thin film transistor array panel including a thin film transistor includes a scanning signal line (or a gate line) for transmitting a scanning signal to the thin film transistor and a data line for transmitting a data signal, as well as a pixel electrode connected to the thin film transistor.

The thin film transistor is formed of a gate electrode that is connected to the gate line, a source electrode that is connected to the data line, a drain electrode that is connected to the pixel electrode, and a semiconductor layer that is disposed on the gate electrode between the source electrode and drain electrode, and the data signal is transmitted to the pixel electrode from the data line according to the gate signal from the gate line.

In this case, the semiconductor layer of the thin film transistor is formed of polysilicon, amorphous silicon, or an oxide semiconductor.

The gate insulating layer or the passivation layer of the thin film transistor may be made of silicon oxide or silicon nitride.

However, a deposition speed of the silicon oxide is slow, etching time is long for dry etching, and many particles are generated during the etching.

Also, the oxide of the oxide semiconductor is reduced by a reducing process of hydrogen when depositing the silicon nitride such that the electrical characteristics of the thin film transistor may be deteriorated.

The above information disclosed in this Background section is only for enhancement of understanding of the background of the invention and therefore it may contain information that does not form the prior art that is already known in this country to a person of ordinary skill in the art.

### SUMMARY OF THE INVENTION

Exemplary embodiments of the present invention provide a thin film transistor array panel that may prevent reduction of electrical characteristics of the thin film transistor, and a manufacturing method thereof.

Additional features of the invention will be set forth in the description which follows, and in part will be apparent from the description, or may be learned by practice of the invention.

An exemplary embodiment of the present invention discloses a thin film transistor array panel including: an insulation substrate; a gate line disposed on the insulation substrate; a data line intersecting the gate line; a thin film transistor connected to the gate line and the data line; a gate insulating layer between the gate electrode of the thin film transistor and the semiconductor of the thin film transistor; a pixel electrode connected to the thin film transistor; and a passivation layer disposed between the pixel electrode and the thin film transistor, wherein at least one of the gate insulating layer and the passivation layer includes a silicon nitride layer, and the silicon nitride layer includes hydrogen at less than 2×10²² cm³ or 4 atomic %.

An exemplary embodiment of the present invention discloses a manufacturing method of a thin film transistor array panel includes: forming a gate line on an insulation substrate; forming a data line intersecting the gate line; forming a thin film transistor connected to the gate line and the data line; forming a passivation layer on the thin film transistor; and forming a pixel electrode positioned on the passivation layer and connected to the thin film transistor, wherein at least one of the passivation layer and the gate insulating layer disposed between the gate electrode and the semiconductor of the thin film transistor includes a silicon nitride layer, and the silicon nitride layer is formed by maintaining a pressure of a deposition chamber at less than 1500 mTorr and a flow ratio of N₂/SiH₄ of more than 80.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a view of a thin film transistor according to an exemplary embodiment of the present invention.

FIG. 2 is a cross-sectional view showing a method of manufacturing the thin film transistor of FIG. 1 according to an exemplary embodiment.

FIG. 3 is a cross-sectional view showing a method of manufacturing the thin film transistor of FIG. 1 according to an exemplary embodiment of the present invention.

FIG. 4 is a graph of an FT-IR analysis comparing the hydrogen content included in a silicon nitride layer formed according to an exemplary embodiment and the conventional art.

FIG. 5 is an I_{ds}-V graph of a thin film transistor including a gate insulating layer and a passivation layer formed according to the conventional art according to an exemplary embodiment.

FIG. 6 is an I_{ds}-V graph of a thin film transistor including a gate insulating layer and a passivation layer formed according to an exemplary embodiment of the present invention.

FIG. 7 is an I_{ds}-V graph of a thin film transistor including a gate insulating layer and a passivation layer formed according to an exemplary embodiment of the present invention.

FIG. 8 is a layout view of a thin film transistor array panel according to an exemplary embodiment of the present invention.

FIG. 9 is a cross-sectional view taken along the line IX-IX of FIG. 8.

### DETAILED DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

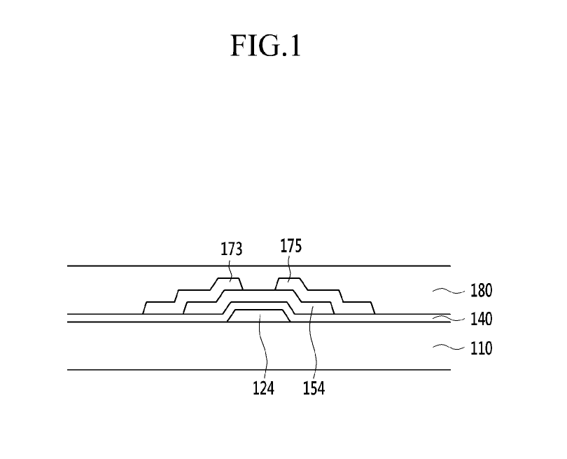

FIG. 1 is a view of a thin film transistor according to an exemplary embodiment of the present invention. Although the thin film transistor of FIG. 1 is shown as a bottom gate thin film transistor, exemplary embodiments of the invention may be used with other configurations, such as a top gate thin film transistor.

As shown in FIG. 1, a gate electrode 124 is formed on a substrate 110, and a gate insulating layer 140 is formed on the gate electrode 124. The gate insulating layer 140 includes a silicon nitride layer, and a hydrogen content in the silicon nitride layer may be less than 2×10²² cm³ or approximately 4 atomic % (atomic percent). A refractive index of the silicon nitride layer may be in the range of 1.86-2.0.

An oxide semiconductor 154 is formed on the gate insulating layer 140. The oxide semiconductor 154 may include an oxide of at least one of: zinc (Zn), gallium (Ga), tin (Sn), or indium (In), e.g., zinc oxide (ZnO), indium-gallium-zinc oxide (InGaZnO4), indium-zinc oxide (Zn—In—O), or zinc-tin oxide (Zn—Sn—O), which are complex oxides thereof. It will be understood that for the purposes of this disclosure, “at least one of” will be interpreted to mean any combination the enumerated elements following the respective language, including combination of multiples of the enumerated elements. For example, “at least one of X, Y, and Z” will be construed to mean X only, Y only, Z only, or any combination of two or more items X, Y, and Z (e.g., XYZ, XZ, YZ).

In exemplary embodiments, the oxide semiconductor 154 has a large effective mobility of charges and an excellent stability characteristic compared with amorphous silicon. In exemplary embodiments, the oxide semiconductor 154 has a good ohmic contact characteristics with a source electrode and a drain electrode such that an additional ohmic contact may not need to be formed.

A source electrode 173 and a drain electrode 175 overlapping the oxide semiconductor 154 and facing each other are formed on the gate insulating layer 140. In exemplary embodiments, the source electrode 173 and the drain electrode 175 may be made of a material capable of forming an ohmic contact with the oxide semiconductor, or multi-layers including a metal having low resistivity.

A passivation layer 180 is formed on the source electrode 173 and the drain electrode 175. In exemplary embodiments, the passivation layer 180 may be formed of the same material as the gate insulating layer 140, or an organic material having a low dielectric constant of less than 4.0.

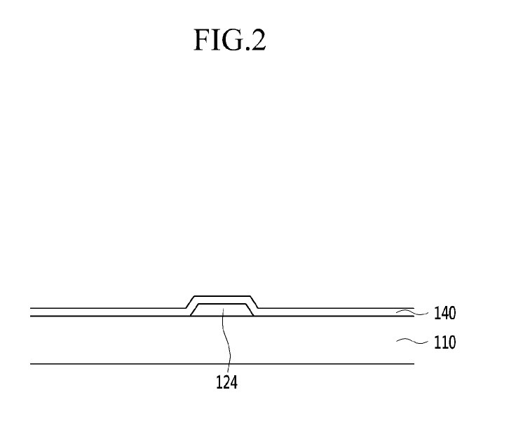

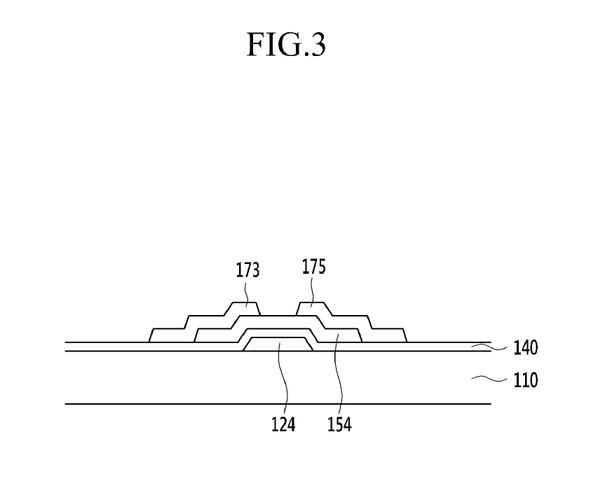

A manufacturing method of the thin film transistor will be described with reference to FIG. 2 and FIG. 3 as well as the above-described FIG. 1.

FIG. 2 is a cross-sectional view showing a method of manufacturing the thin film transistor of FIG. 1 according to an exemplary embodiment of the present invention.

In FIG. 2, a metal layer is formed on a substrate 110 and then patterned to form a gate electrode 124.

The gate insulating layer 140 is formed on the gate electrode 124. The gate insulating layer 140 may be formed by reactive chemical vapor deposition or physical vapor deposition such as sputtering. For example, low temperature chemical vapor deposition or low temperature physical vapor deposition may be used to form the gate insulating layer 140.

The gate insulating layer 140 includes a silicon nitride layer. The production process of the silicon nitride layer is controlled to minimize the number of radicals of hydrogen (H) that may be generated in the deposition process of the silicon nitride layer such that the silicon nitride layer includes hydrogen at less than 2×10²² cm³ or approximately 4 atomic % (atomic percentage). In an exemplary embodiment, the ratio of a Si—H stretching area to N—H stretching area in the silicon nitride layer may be more than 1.

For example, when forming the silicon nitride layer through low temperature chemical vapor deposition, the power may be set to 1000 W, the pressure may be set to 1000 mT, and the temperature may be set to 280° C. In addition, N₂ gas at 8000 sccm and SiH₄ at 100 sccm are injected to obtain a content of hydrogen of 1.5×10²² cm³ in the gate insulating layer.

Alternatively, when injecting SiH₄ at 80 sccm, the hydrogen content may be 1.4×10²² cm³ in the gate insulating layer.

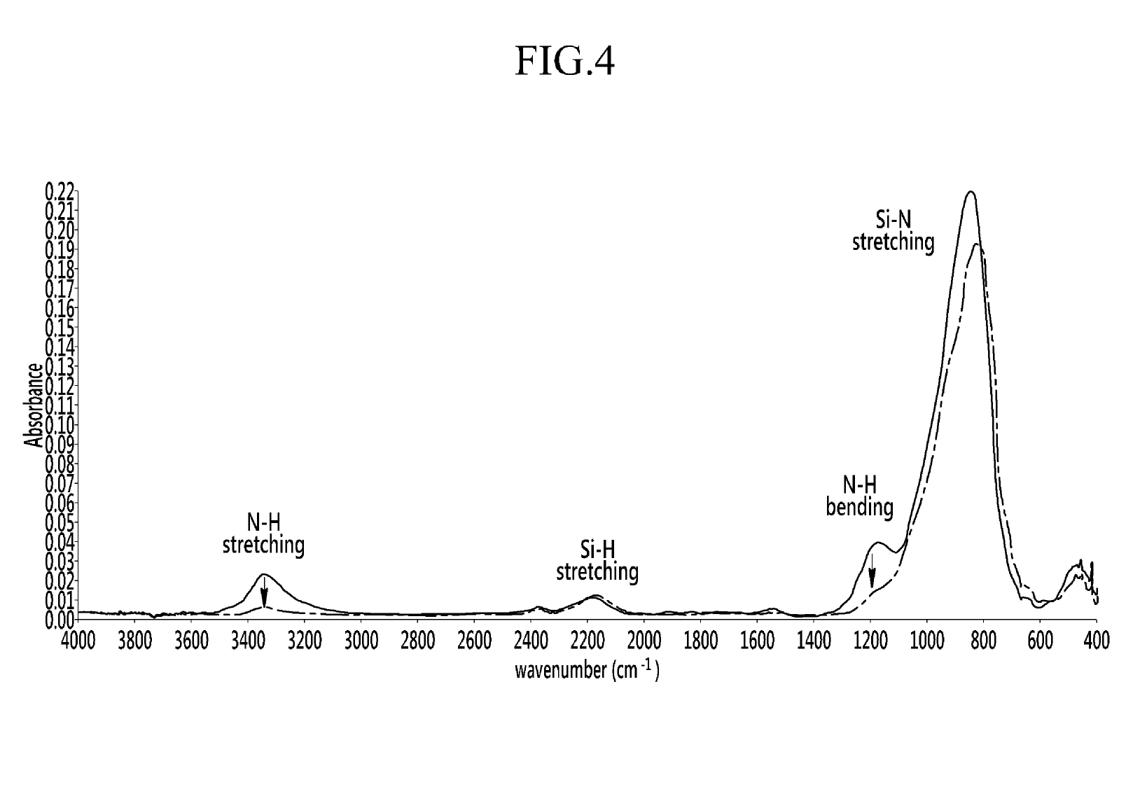

FIG. 4 is a graph of an FT-IR analysis comparing the hydrogen content included in a silicon nitride layer formed according to an exemplary embodiment and the conventional art. The red line is a line depicting measured hydrogen content in a silicon nitride layer according to an exemplary embodiment of the present invention, and a green line is a line depicting measured hydrogen content in a silicon nitride layer according to the conventional art.

Referring to FIG. 4, absorption peak of an N—H bending in the graph according to an exemplary embodiment of the present invention is decreased compared with the N—H bending absorption peak of the conventional art.

FIG. 3 is a cross-sectional view showing a method of manufacturing the thin film transistor of FIG. 1 according to an exemplary embodiment of the present invention.

As shown in FIG. 3, an oxide semiconductor 154 is formed on the gate insulating layer 140. In an exemplary embodiment, the oxide semiconductor 154 may be formed by coating and patterning an oxide semiconductor material. However, aspects need not be limited thereto such that the oxide semiconductor material may be formed by an inkjet method as a solution. If forming the oxide semiconductor through the inkjet method, a partition enclosing the oxide semiconductor may be formed.

A metal layer is formed on the oxide semiconductor 154 and patterned to form a source electrode 173 and a drain electrode 175.

As shown in FIG. 1, a passivation layer 180 is formed on the source electrode 173 and the drain electrode 175.

In an exemplary embodiment, the passivation layer 180 may be made of two layers of silicon nitride. The silicon nitride layer may be formed by the same method as the silicon nitride layer of the gate insulating layer 140 such that the hydrogen content is less than 2×10²² cm³ or 4 atomic % (atomic percentage) in the silicon nitride layer. In an exemplary embodiment, the ratio of the Si—H stretching area to N—H stretching area may be more than 1 in the silicon nitride layer.

When forming the gate insulating layer 140 or the passivation layer 180 including the silicon nitride layer through the method according to the exemplary embodiments of the present invention, a thin film transistor array panel having improved electric characteristics compared with the conventional thin film transistor may be obtained.

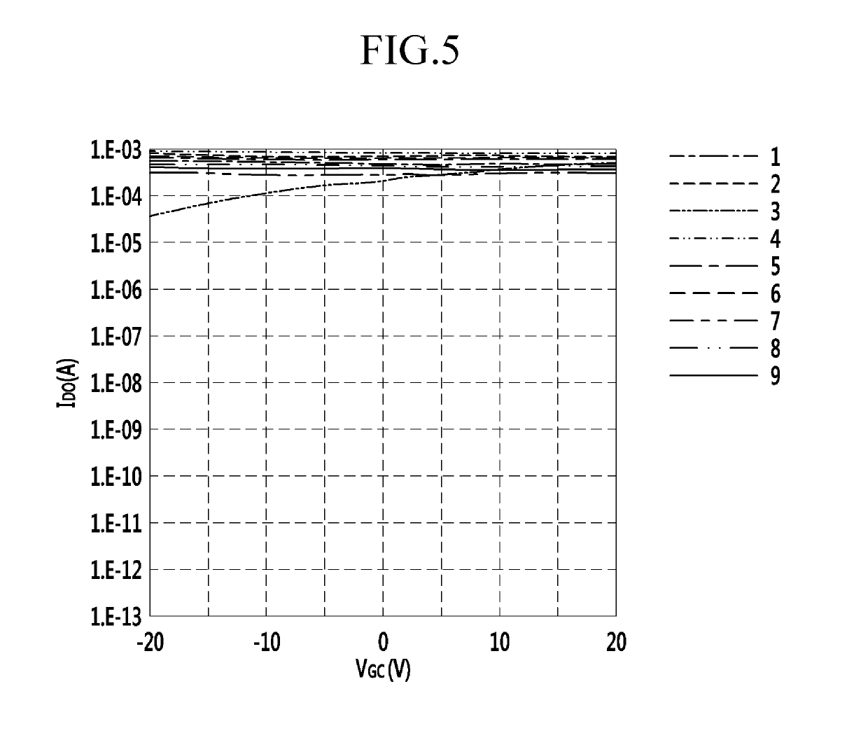

FIG. 5 is an I_{ds}-V graph of a thin film transistor including a gate insulating layer and a passivation layer formed according to the conventional art.

The gate insulating layer and the passivation layer may be formed of dual layers, a thin film with a high density is formed at a portion that contacts the channel, and a thin film with a low density and a short deposition time is formed at a portion that does not contact the channel to decrease the leakage current.

The gate insulating layer of FIG. 5 includes a first gate insulating layer made of a silicon nitride layer of low density with a thickness of 4000 Å at a temperature of 370° C., and a second gate insulating layer made of a silicon nitride layer of a high density with a thickness of 500 Å at a temperature of 370° C. The passivation layer is made of a silicon nitride layer with a thickness of 2000 Å at a temperature of 245° C.

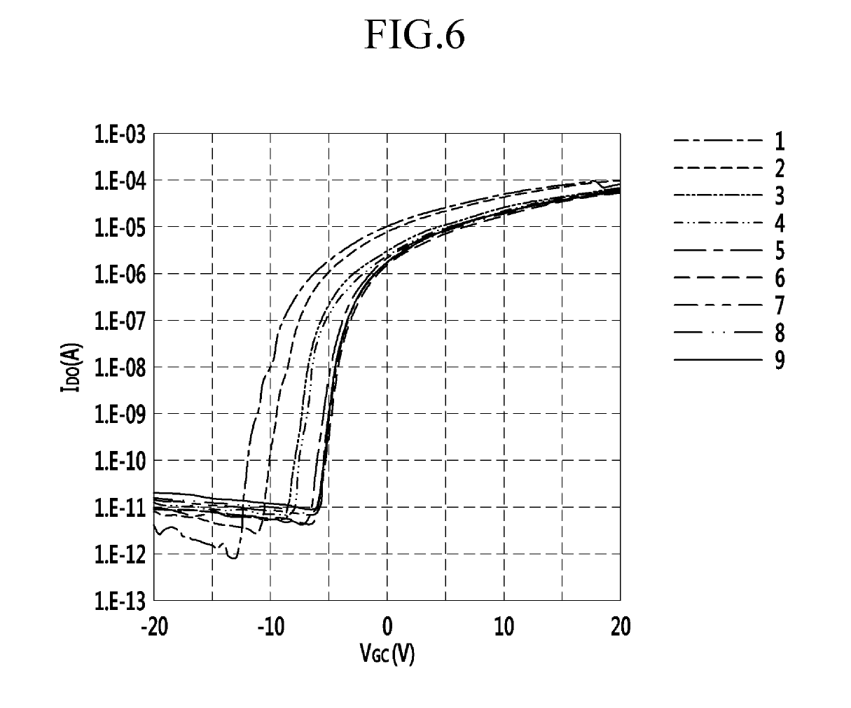

FIG. 6 is an I_{ds}-V graph of a thin film transistor including a gate insulating layer and a passivation layer formed according to an exemplary embodiment of the present invention.

The gate insulating layer of FIG. 6 is formed by using N₂ gas at 3000 sccm to 8000 sccm and SiH₄ at more than 100 sccm to less than 140 sccm such that the ratio of N₂ to SiH₄ is less than 80.

The gate insulating layer of FIG. 6 includes the first gate insulating layer made of a silicon nitride layer of low density with a thickness of 4000 Å at a temperature of 370° C., and a second gate insulating layer made of a silicon nitride layer of high density with a thickness of 500 Å at a temperature of 370° C. The passivation layer includes a first passivation layer made of a silicon nitride layer of high density with a thickness of 2000 Å at a temperature of 150° C. and a second passivation layer made of a silicon nitride layer of low density with a thickness of 1000 Å at a temperature of 245° C.

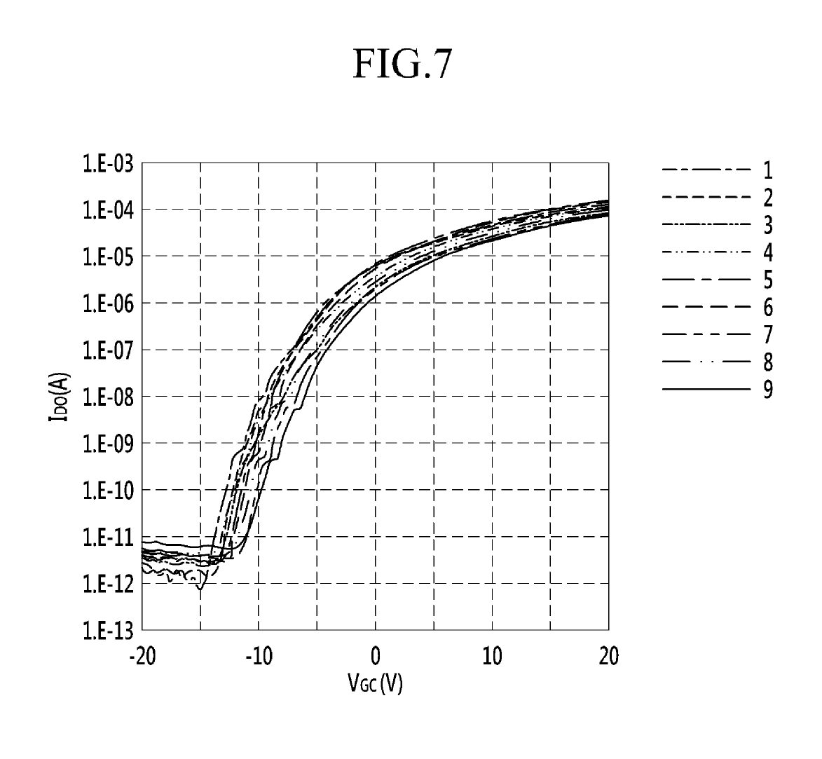

FIG. 7 is an I_{ds}-V graph of a thin film transistor including a gate insulating layer and a passivation layer formed according to an exemplary embodiment of the present invention.

The gate insulating layer of FIG. 7 includes a first gate insulating layer made of a silicon nitride layer of a low density with a thickness of 4,000 Å at a temperature of 370° C. and a second gate insulating layer made of a silicon nitride layer of a high density with a thickness of 500 Å at a temperature of 370° C. The passivation layer includes a first passivation layer made of a silicon nitride layer of a high density with a thickness of 2,000 Å at a temperature of 245° C. and a second passivation layer made of a silicon nitride layer of a low density with a thickness of 1,000 Å at a temperature of 245° C.

The second gate insulating layer of FIG. 6 and the first passivation layer of FIG. 7 are formed according to an exemplary embodiment of the present invention by injecting N₂ gas at 8000 sccm and SiH₄ at 80 sccm to 100 sccm, thus the ratio of N₂ to SiH₄ may be more than 80 resulting in the hydrogen content in the second gate insulating layer of FIG. 6 and the first passivation layer of FIG. 7 being approximately 1.5×10²² cm³.

Referring again to FIG. 5, the thin film transistor, according to the conventional art, does not have characteristics of a semiconductor, but rather characteristics of a conductor. In contrast, the I_{ds}-V graphs of FIG. 6 and FIG. 7 depict that characteristics of an expected semiconductor I_{ds}-V graph. Furthermore, the deviations of the I_{ds}-V curves 1 to 9 of FIG. 6 from I_{ds}-V curves 1 to 9 of FIG. 7 are not substantial.

A thin film transistor array panel including the above-described thin film transistor will be described.

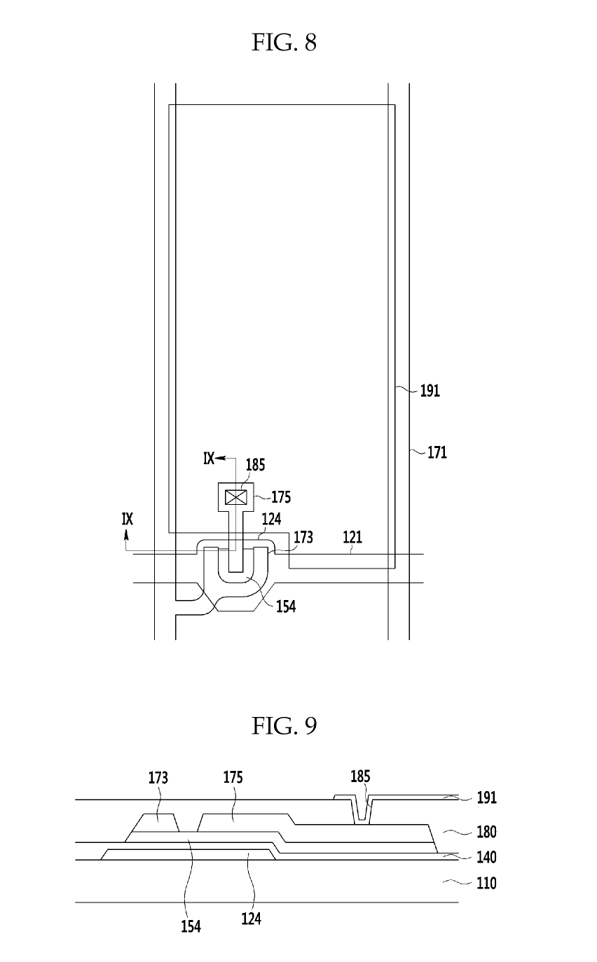

FIG. 8 is a layout view of a thin film transistor array panel according to an exemplary embodiment of the present invention. FIG. 9 is a cross-sectional view taken along the line IX-IX of FIG. 8.

As shown in FIG. 8 and FIG. 9, multiple gate lines 121 transmitting gate signals are formed on an insulation substrate 110 made of a material such as transparent glass or plastic. The gate line 121 extends in a transverse direction and includes a gate electrode 124.

A gate insulating layer 140 is formed on the gate line 121. The gate insulating layer 140 may be a single layer made of silicon nitride; however, it may be formed of two layers of a thin film having different densities. Two layers may be considered to reduce the leakage current and the deposition time of the layers. In an exemplary embodiment, a first silicon nitride layer having a fast deposition speed and a low density may be formed, and a second silicon nitride layer having a slow deposition speed and high density may be formed. The use of these two layers decreases the leakage current because the second silicon nitride layer with a high density is formed on the first silicon nitride layer with a low density. The gate insulating layer 140 may be formed with the thickness in the range of 2000 Å to 5000 Å.

In an exemplary embodiment, the hydrogen content of the silicon nitride layer may be 1.4×10²² cm³. If forming the gate insulating layer 140 using multiple layers, the hydrogen content of the layer positioned at the upper portion may be lower than the hydrogen content of the layer positioned at the lower portion.

An oxide semiconductor 154 overlapping the gate electrode 124 and is formed on the gate insulating layer 140.

The oxide semiconductor 154 may include an oxide of at least one of zinc (Zn), gallium (Ga), tin (Sn), or indium (In), e.g., zinc oxide (ZnO), indium-gallium-zinc oxide (InGaZnO4), indium-zinc oxide (Zn—In—O), or zinc-tin oxide (Zn—Sn—O), which are complex oxides thereof.

Multiple data lines 171 and multiple drain electrodes 175 are formed on the oxide semiconductor 154 and the gate insulating layer 140.

The data line 171 extends in a longitudinal direction and intersects the gate line 121. The data line 171 transmits the data voltage. The data line 171 includes a source electrode 173 overlapping the oxide semiconductor 154.

The drain electrode 175 overlaps the oxide semiconductor 154 and faces the source electrode 173 when viewed with respect to the gate electrode 124.

The gate electrode 124, the source electrode 173, and the drain electrode 175 form the thin film transistor (TFT) along with the oxide semiconductor 154, and the channel formed on the oxide semiconductor 154 between the source electrode 173 and the drain electrode 175.

A passivation layer 180, which protects the channel, is formed on the data line 171 and the drain electrode 175. In an exemplary embodiment, the passivation layer 180 may include the silicon nitride layer.

In an exemplary embodiment, the passivation layer 180 may be formed with an equal area to that of the gate insulating layer 140, and may be made of a single layer or multiple layers.

The passivation layer 180 includes a contact hole 185 exposing the drain electrode 175.

A pixel electrode 191 connected to the drain electrode 175 through the contact hole 185 is formed on the passivation layer 180. The pixel electrode 191 may be made of a transparent conductive material.

In the present invention, the hydrogen content of the gate insulating layer is such that the electrical characteristics of the thin film transistor may be improved through the use of a gate insulating layer made of silicon nitride and without the usage of a gate insulating layer made of silicon oxide.

Furthermore, by not using silicon oxide to form the gate insulating layer or the passivation layer the particles that may be generated or reduced during etching are not present in the present invention. Thereby a high quality thin film transistor array panel may be generated.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor array panel comprising:
a substrate;
a gate line positioned on the substrate;
a data line intersecting the gate line;
a thin film transistor connected to the gate line and the data line, the thin film transistor comprising a semiconductor;
a gate insulating layer disposed between the gate electrode of the thin film transistor and the semiconductor of the thin film transistor;
a pixel electrode connected to the thin film transistor; and
a passivation layer disposed between the pixel electrode and the thin film transistor,
wherein at least one of the gate insulating layer and the passivation layer comprises a silicon nitride layer, and
the silicon nitride layer comprises hydrogen at less than 2×10²² cm³ or 4 atomic %.

2. The thin film transistor array panel of claim 1, wherein
the silicon nitride layer comprises a first silicon nitride layer having a first density and a second silicon nitride layer having a second density and wherein the first density and second density are different.

3. The thin film transistor array panel of claim 2, wherein
a refractive index of the silicon nitride layer is in the range of 1.86-2.0.

4. The thin film transistor array panel of claim 2, wherein
the first silicon nitride layer is disposed closer to the semiconductor than the second silicon nitride layer.

5. The thin film transistor array panel of claim 4, wherein
the first density of the first silicon nitride layer is higher than the second density of the second silicon nitride layer.

6. The thin film transistor array panel of claim 1, wherein
the oxide semiconductor is made of an oxide of at least one of zinc (Zn), gallium (Ga), tin (Sn), or indium (In), or combinations thereof.

7. The thin film transistor array panel of claim 1, wherein
the oxide semiconductor is made of at least one of zinc oxide (ZnO), indium-gallium-zinc oxide (InGaZnO4), indium-zinc oxide (Zn—In—O), or zinc-tin oxide (Zn—Sn—O).

8. The thin film transistor array panel of claim 4, wherein
the first density of the first silicon nitride layer is lower than the second density of the second silicon nitride layer.

9. A method for manufacturing a thin film transistor array panel, comprising:
forming a gate line on a substrate;
forming a data line intersecting the gate line;
forming a thin film transistor connected to the gate line and the data line;
forming a passivation layer on the thin film transistor; and
forming a pixel electrode disposed on the passivation layer and connected to the thin film transistor,
wherein at least one of the passivation layer and the gate insulating layer, disposed between the gate electrode and the semiconductor of the thin film transistor, comprises a silicon nitride layer, and
the silicon nitride layer is formed by maintaining a pressure of a deposition chamber at less than 1500 mTorr and a flow ratio of N₂/SiH₄ of more than 80.

10. The method of claim 9, wherein
the silicon nitride layer comprises hydrogen at less than 2×10²² cm³.

11. The method of claim 9, wherein
the silicon nitride layer comprises hydrogen at less than 4 atomic % (atomic percentage).

12. The method of claim 9, wherein
the refractive index of the silicon nitride layer is in the range of 1.86-2.0.

13. The method of claim 10, wherein
at least one of the gate insulating layer and the passivation layer comprises a first silicon nitride layer having a first density and a second silicon nitride layer having a second density, wherein the first density and the second density are different.

14. The method of claim 13, wherein
the first density of the first silicon nitride layer is higher than the second density of the second silicon nitride layer.

15. The method of claim 13, wherein
the first density of the first silicon nitride layer is lower than the second density of the second silicon nitride layer.

16. The method of claim 13, wherein
the semiconductor comprises an oxide semiconductor.

17. The method of claim 16, wherein
the oxide semiconductor is made of an oxide of at least one of zinc (Zn), gallium (Ga), tin (Sn), indium (In), or a combination thereof.

18. The method of claim 16, wherein
the oxide semiconductor is made of at least one of zinc oxide (ZnO), indium-gallium-zinc oxide (InGaZnO4), indium-zinc oxide (Zn—In—O), or zinc-tin oxide (Zn—Sn—O).

19. Thin film transistor array panel of claim 1, wherein
the hydrogen content in the silicon nitride layer is approximately 1.5×10²² cm³.

20. Thin film transistor array panel of claim 1, wherein
the hydrogen content in the silicon nitride layer is approximately 1.4×10²² cm³.

21. The method of claim 10, wherein
the hydrogen content in the in the silicon nitride layer is approximately 1.5×10²² cm³.

22. The method of claim 10, wherein
the hydrogen content in the in the silicon nitride layer is approximately 1.4×10²² cm³.

23. A thin film transistor, comprising:
a substrate;
a control electrode arranged on the substrate;
an input electrode and an output electrode;
a semiconductor disposed between the control electrode and the input and output electrodes; and
an insulating layer disposed between the control electrode and the semiconductor,
wherein the insulating layer comprises a silicon nitride layer comprising hydrogen at less than 2×10²².cm³.

24. The thin film transistor of claim 23, wherein the silicon nitride layer comprises a first silicon nitride layer having a first density and a second silicon nitride layer having a second density, and wherein the first density and second density are different.
